(19) United States
(12) Patent Application Publication
(10) Pub. No.: US 2026/0122945 A1
(43) Pub. Date: Apr. 30, 2026

(54) MANUFACTURING PROCESS FOR VERTICAL GaN-BASED MICROELECTRONIC DEVICES

(71) Applicant: COMMISSARIAT A L'ENERGIE ATOMIQUE ET AUX ENERGIES ALTERNATIVES, Paris (FR)

(72) Inventors: Julien BUCKLEY, Grenoble Cedex (FR); Matthew CHARLES, Grenoble Cedex (FR); Jérôme BISCARRAT, Grenoble Cedex (FR); Thomas KALTSOUNIS, Grenoble Cedex (FR); Philippe GODIGNON, Grenoble Cedex (FR); Mohammed EL AMRANI, Grenoble Cedex (FR); David PLAZA ARGUELLO, Grenoble Cedex (FR); Hala EL RAMMOUZ, Grenoble Cedex (FR)

(73) Assignee: COMMISSARIAT A L'ENERGIE ATOMIQUE ET AUX ENERGIES ALTERNATIVES, Paris (FR)

(21) Appl. No.: 19/358,616

(22) Filed: Oct. 15, 2025

(30) Foreign Application Priority Data
Oct. 16, 2024 (FR) FR2411189

(51) Int. Cl. H10D 30/01; C30B 25/04; C30B 25/18; C30B 29/40; C30B 31/22; H10P 14/20

(52) U.S. Cl. CPC H10D 30/0291; C30B 25/04; C30B 25/18; C30B 29/406; C30B 31/22; H10P 14/3416

(57) ABSTRACT

A method is provided for manufacturing at least one microelectronic device including a vertical transistor. The method includes providing a substrate having an upper face and performing localized epitaxial growth of gallium nitride on the upper face to form at least one GaN-based island. Each island includes a GaN-based drift layer having opposite upper and lower faces. A first doped GaN-based layer of a first conductivity type is formed on each island to define a plurality of separated doped wells extending from the upper face of the drift layer. An electrically conductive layer forming a drain is electrically connected to the lower face of each GaN-based island, thereby forming at least one vertical transistor.

### TECHNICAL FIELD

The present invention relates to the field of microelectronic devices, in particular, GaN-based components. It has, for example, a particularly advantageous application in the field of power electronics.

### PRIOR ART

The main microelectronic devices, and in particular, transistors and diodes, can be designed according to numerous transistor architectures, among which, vertical microelectronic devices. The properties of vertical transistors, for example, are, today, particularly utilised in power electronics applications.

GaN-based vertical devices are typically manufactured by epitaxy from GaN substrates. However, GaN substrates available in the industry are of a low diameter. The current methods for manufacturing GaN vertical devices on a GaN substrate do not therefore make it possible to simultaneously manufacture a quantity of devices comparable to what is produced on substrate with a larger diameter (silicon substrates, typically). These methods are moreover very expensive, due to the high price of GaN substrates.

An aim of the present invention is thus to propose a method for manufacturing GaN-based vertical transistors, resolving at least some of the problems stated above.

### SUMMARY

To achieve this aim, according to an embodiment, a method for manufacturing at least one microelectronic device comprising the following steps:
providing a substrate having an upper face,
performing a localized gallium nitride (GaN) epitaxy on the upper face of the substrate, so as to form at least one GaN-based island, each island having a face, called lower, facing the upper face of the substrate, each island comprising a layer called GaN-based drift layer, the drift layer having a lower face facing the upper face of the substrate and an upper face opposite the lower face,
at each island, forming a first doped GaN-based layer of a first type taken from among an n-type doping and a p-type doping, the first layer forming a plurality of doped wells separated from one another and each extending from the upper face of the drift layer,
forming an electrically conductive layer forming a drain, the drain being electrically connected to the lower face of each island, thus forming at least one vertical transistor.

Thus, the method according to the invention makes it possible to initiate the formation of devices on a large and inexpensive substrate, such as a silicon substrate. Thus, having to resort to an expensive and small GaN substrate is avoided. The steps of forming gates and source contacts, anodes or other usual elements can be carried out, while the islands rest on the substrate, or after removal of this substrate. The formation of the drain in the rear face simply requires to remove the substrate beforehand, by grinding and/or CMP and/or etching, or to make metal interconnections in the substrate, which is absolutely reasonable in the case of a silicon substrate. Thus, fully vertical GaN devices are obtained, without having to sacrifice a GaN substrate.

The local epitaxy of GaN can further make it possible to form islands of a height going up to 10 μm, even 20 μm. Thanks to this, the transistors formed by the method can support voltages as high as 1200V, even 2200V.

Moreover, the method makes it possible to effectively manufacture vertical devices with a very high substrate coverage rate. For hexagonal islands, for example, the surface lost due to gaps between islands is between 5 to 10% of the total surface, which is very low. Thus, the method according to the invention enables an effective, large-scale and inexpensive manufacture of GaN-based vertical devices. The manufactured devices are moreover very compact and robust.

### BRIEF DESCRIPTION OF THE FIGURES

The aims, objectives, as well as the features and advantages of the invention will best emerge from the detailed description of an embodiment of the latter, which is illustrated by the following accompanying drawings, in which:

FIGS. 1A to 1I illustrate a first embodiment of the method according to the invention making it possible to manufacture diodes.

FIGS. 1E and 1F illustrate an example, in which the substrate is removed and the drain is formed in direct contact with the islands.

FIGS. 1H and 1I illustrate an example, in which metal interconnections are formed in the substrate and the drain is formed in contact with these interconnexions.

FIGS. 2A to 2J illustrate a second embodiment of the method according to the invention, making it possible to manufacture transistors.

FIGS. 3A to 3C are images obtained by scanning electron microscopy (SEM) of crude GaN islands by localized epitaxy.

FIG. 3B is a magnification of FIG. 3A.

FIG. 3C is a magnification of FIG. 3B.

The drawings are given as examples and are not limiting of the invention. They constitute principle schematic representations, intended to facilitate the understanding of the invention, and are not necessarily to the scale of practical applications. In particular, the dimensions are not representative of reality.

### DETAILED DESCRIPTION

Before starting a detailed review of embodiments of the invention, optional features are stated below, which can optionally be used in association or alternatively:

According to an example, the substrate is silicon-based.

According to an example, each island has a height h₁₀₀ greater than or equal to 10 μm, preferably greater than or equal to 20 μm, h₁₀₀ being measured in a direction perpendicular to a plane into which the upper face of the substrate mainly extends.

According to an embodiment, the step of forming the drain comprises the following steps:
after formation of the at least one island, removing the substrate, then
forming the drain against the lower face of the at least one island.

According to an embodiment, the step of forming the drain comprises the following steps:
for each island, forming at least one metal interconnection passing through the substrate and opening onto said island,
forming the drain against a lower face of the substrate opposite its upper face, the drain being in contact with the at least one metal interconnection.

According to a particular embodiment, the method according to the invention is a method for manufacturing at least one vertical transistor and further comprises the following steps:
at each island, partially implanting the first layer, so as to form at least one pair of regions, called sources, doped of the other type from among an n-type doping and a p-type doping, the sources of one same pair of sources being located in distinct doped wells,
forming at least one gate in contact with the two sources of one same pair of sources, the at least one gate comprising an electrically conductive pattern,
forming an electrically conductive contact called source contact in contact with each source of one same pair of sources.

According to an example, the first layer forms at least three doped wells and in which at least two pairs of sources are formed in these at least three doped wells, two sources belonging to pairs of distinct sources being formed in one same doped well.

According to an example, the source contacts in contact with the sources formed in one same doped well are in electrical continuity and form a source contact common to the two transistors.

According to an example, the step of removing the substrate is carried out before the formation of the source contact, optionally before the formation of the gate, optionally before the step of implanting and of forming the sources.

According to an example, the step of removing the substrate is carried out after the step of implanting and of forming the sources, optionally after the formation of the gate, optionally after the formation of the source contact.

According to an embodiment, the step of forming the first layer comprises the following steps:
at each island, forming in the drift layer, at least one opening extending from the upper face of the drift layer,
at each island, forming the first layer in each of the openings in the drift layer of the island, the first layer thus forming the plurality of doped wells.

According to an embodiment, the step of forming the first layer comprises the following steps:
at each island, forming on the drift layer, a doped GaN continuous layer of the first type,
at each island, forming in the GaN continuous layer, secondary openings separated from one another and fully passing through said doped GaN continuous layer, so as to partially reveal the drift layer, the remaining portions of the continuous layer forming the first layer,
at each island, making the drift layer epitaxially grow in the secondary openings. According to a particular embodiment, the method according to the invention is a method for manufacturing at least one diode and further comprises the following step:
forming an electrically conductive pattern called anode in contact with at least two doped wells, preferably with all the doped wells.

According to an example, the step of removing the substrate is carried out before the formation of the anode.

According to an example, the step of removing the substrate is carried out after the formation of the anode.

It is specified that, in the scope of the present invention, the terms “on”, “surmounts”, “covers”, “underlying”, “opposite” and their equivalents do not necessarily mean “in contact with”. Thus, for example, the deposition, the transfer, the bonding, the assembly or the application of a first layer on a second layer, does not compulsorily mean that the two layers are directly in contact with one another, but means that the first layer at least partially covers the second layer by being, either directly in contact with it, or by being separated from it by at least one other layer or at least one other element.

A layer can moreover be composed of several sublayers of one same material or of different materials.

By a substrate, a layer, a device “with the basis” of a material M, this means a substrate, a layer, a device comprising this material M only, or this material M and optionally other materials, for example, alloy elements, impurities or doping elements.

By “selective etching with respect to” or “etching having a selectivity with respect to” an etching configured to remove a material A or a layer A with respect to a material B or a layer B, and having an etching speed of the material A greater than the etching speed of the material B. The selectivity is the ratio between the etching speed of the material A over the etching speed of the material B. The selectivity between A and B is referenced SA:B.

Two elements are called “electrically connected” when they are each in contact with one same continuous electrical connection element having an electrical conduction preferably greater than 10⁷ S/m.

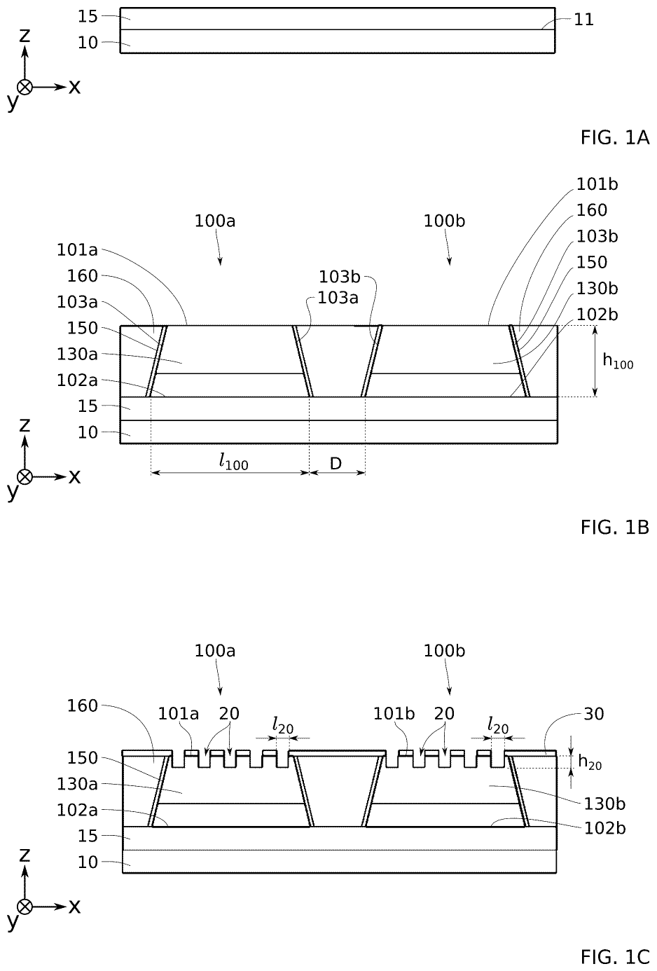

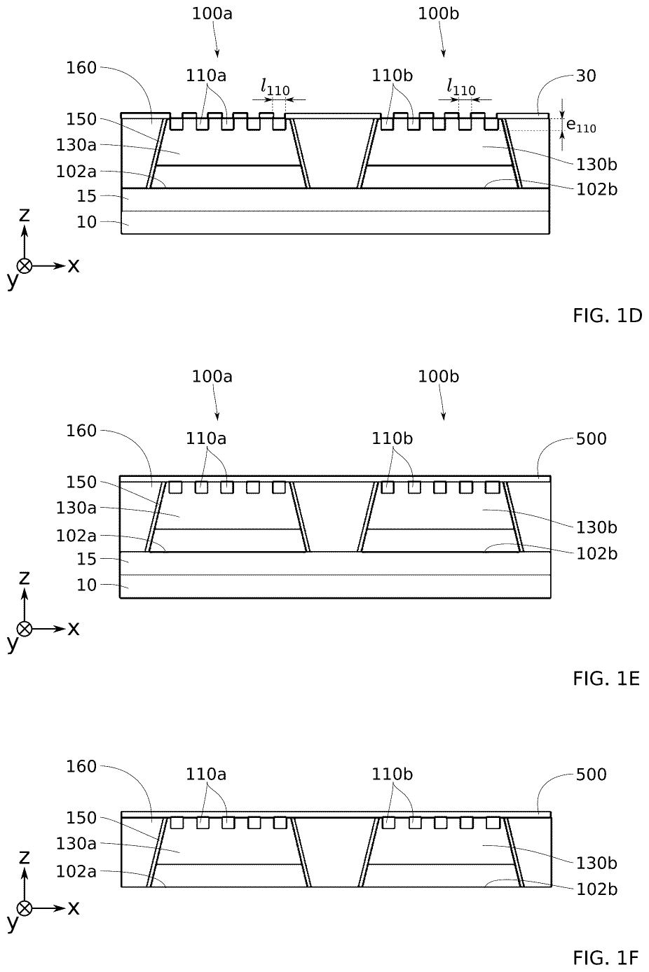

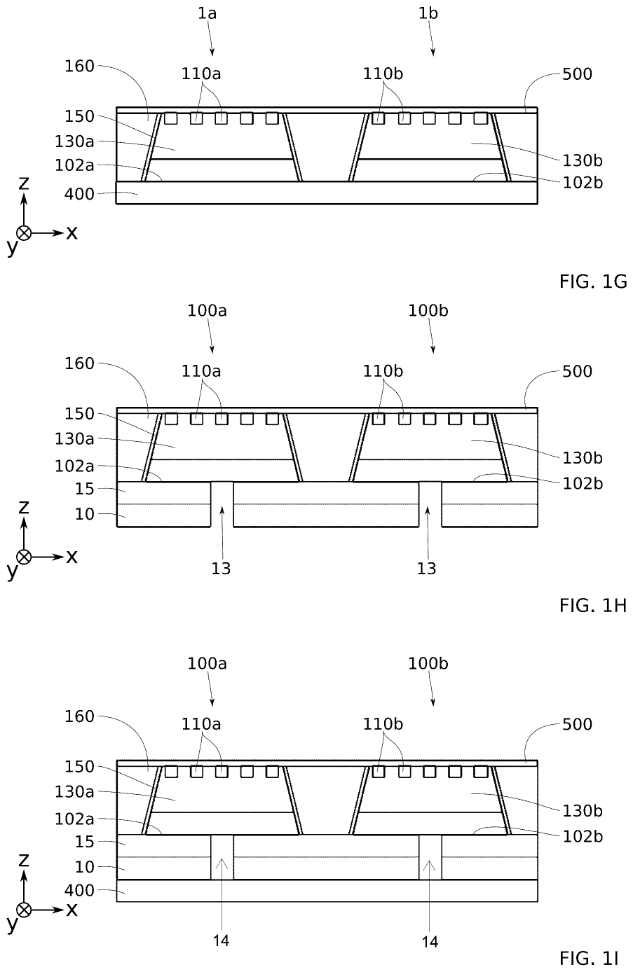

A preferably orthonormal system, comprising the axes X, Y, Z is represented in FIG. 1A. This system is applicable by extension to the other figures. The direction Z can be called “stacking direction”.

In the present patent application, thickness will preferably be referred to for a layer, and height will preferably be referred to for a structure or a device. The height is taken perpendicularly to the longitudinal plane XY. The thickness is taken along a direction normal to the main extension plane of the layer. Thus, a layer typically has a thickness along Z, when it extends mainly along the longitudinal plane XY, and a projecting element, for example, an insulation trench, has a height along Z. The relative terms “on”, “under”, “above” “below”, “underlying”preferably refer to positions taken along the direction Z.

The terms “substantially”, “around”, “about” mean “plus or minus 10%, preferably plus or minus 5%”.

A first embodiment of the method according to the invention making it possible to manufacture the diodes 1a, 1b will now be described in reference to FIGS. 1A to 1G. These figures illustrate the simultaneous formation of two diodes 1a, 1b, but it is understood that a greater number of diodes can be simultaneously manufactured by the method according to the invention.

FIG. 1A illustrates the provision of a substrate 10. This substrate 10 is typically silicon-based. It has an upper face 11 extending mainly in a plane XY being able to be called longitudinal plane XY. This plane is defined by a first direction X and a second direction Y. The substrate 10 further has a lower face 12 opposite its upper face 11.

Advantageously, buffer layers 15 are deposited on the upper face 11 of the substrate 10. These buffer layers 15 can, for example, each be with the basis of one of the following materials: GaN, AlN, AlGaN, BN.

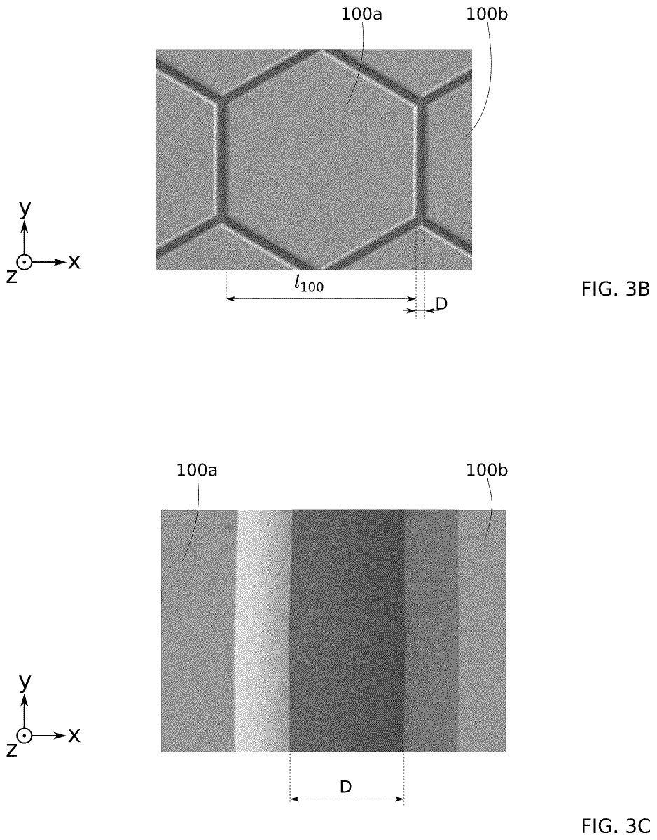

As illustrated in FIG. 1B, GaN-based islands 100a, 100b are then locally crude by epitaxy on the upper face 11 of the substrate 10. Typically, these islands 100a, 100b are crude from the buffer layers 15. FIG. 3A illustrates the experimental result of this step: it constitutes a top view obtained by SEM of a set of islands crude by localized epitaxy on a silicon substrate. It can, in particular, be assessed on this image, that a large number of islands can be simultaneously crude by localized epitaxy.

The islands 100a, 100b are separated from one another. Thus, preferably, no residual, GaN continuous layer is found on the upper face 11 of the substrate 10 (except for optional buffer layers being able to comprise GaN).

The islands 100a, 100b each have a lower face 102a, 102b located facing the upper face 11 of the substrate 10, and typically in contact with the buffer layers 15. Moreover, they each have an upper face 101a, 101b opposite the lower face 102a, 102b.

The step of epitaxially growing the GaN islands 100a, 100b is advantageously configured to form GaN layers within each island 100a, 100b having different dopings. According to an advantageous example, the islands 100a, 100b comprise, from the lower faces 102a, 102b of the islands 100a, 100b to their upper faces 101a, 101b, an n+-doped GaN layer and an n−-doped GaN layer, being able to be called drift layer 130a, 130b.

Fully conventionally, the doping of the n-doped layers can be silicon (Si) or germanium (Ge) and the doping of the p-doped layers can be magnesium (Mg).

The islands 100a, 100b have a characteristic dimension in the plane XY referenced I₁₀₀. Projecting into the plane XY, the islands 100a, 100b typically each have a hexagonal shape, as can be observed in FIG. 3A. In this case, the characteristic dimension I₁₀₀ corresponds to the distance between two flanks of the islands 100a, 100b facing one another. In FIG. 3B, I₁₀₀ is, for example, measured along the first direction X. I₁₀₀ is preferably greater than 100 μm, and preferably less than or equal to 200 μm.

The lateral flanks 103a, 103b of the islands 100a, 100b are typically inclined with respect to the stacking direction Z, as illustrated in the figures. I₁₀₀ is thus measured at the base of the islands 100a, 100b, at their lower face 102a, 102b.

The islands 100a, 100b have a height h₁₀₀ measured along the direction Z (also called stacking direction Z) perpendicular to the longitudinal plane XY. The height h₁₀₀ is preferably greater than 10 μm even 20 μm.

In the longitudinal plane XY, the islands 100a, 100b are separated by a distance D (taken along the first direction X in FIGS. 1B, 3B and 3C). D is measured at the foot of the islands 100a, 100b, i.e. at the height along Z at which the lower faces 102a, 102b of the islands 100a, 100b are located. The distance D is typically greater than 5 μm. The distance D is preferably less than 20 μm even less than 15 μm, even 10 μm. D is typically between 10 and 15 μm. This makes it possible to manufacture transistors with a better density. It is, for example, substantially equal to 8 μm.

The numerical values given above are also valid for the second embodiment which will be described further.

As is also illustrated in FIG. 1B, the lateral flanks 103a, 103b of the islands 100a, 100b are advantageously covered with a passivation layer 150. The passivation layer 150 is, for example, alumina- or SiN-based.

The spaces left empty between the islands 100a, 100b are preferably filled by a filling layer 160 with the basis of a dielectric material, for example, silica-or tetraethyl orthosilicate (TEOS)-based. The deposition of the filling layer 160 can be done by chemical vapour deposition (CVD). Advantageously, this deposition is done according to a low stress method. The deposition of the filling layer 160 can be followed by a planarisation step at the upper face 101a, 101b of the islands 100a, 100b.

An etching step is then carried out from the upper faces 101a, 101b of the islands 100a, 100b (FIG. 1C). This etching step is configured to form at least one opening 20, and preferably, a plurality of openings 20, in each island 100a, 100b. Each opening 20 fully passes through the drift layer 130a, 130b. As will appear further, the dimensions of the openings 20 condition those of the active zones of the diodes 1a, 1b. The openings 20 have, for example a width I₂₀ along the first direction X, with I₂₀ between 100 nm and 4000 nm. Along to the second direction Y, the openings 20 can fully pass through the islands 100a, 100b. The openings 20 further have a height h₂₀ along the stacking direction Z. h₂₀ is typically greater than or equal to 400 nm.

Fully conventionally, this etching step can be carried out by a dry etching through a masking layer 30, as illustrated in FIG. 1C. For this, conventional photolithography steps can be used. The masking layer 30 can, for example, be made of alumina, SiN, SiO₂ or also be an SiO₂/Al₂O₃ multilayer.

During a step illustrated in FIG. 1D, a first layer 110a, 110b is formed by epitaxy in the openings 20 of each island 100a, 100b. The first layer 110a, 110b is doped GaN-based. Its doping can be n-type or p-type. With the first layer 110a being formed in the openings 20, it is discontinuous. It thus forms, in the drift layer 130a, 130b, doped regions, separated from one another, called doped wells. The width I₁₁₀ of each doped well is substantially equal to the width I₂₀ of the openings 20. The same applies for the thickness e₁₁₀ of the doped wells, substantially equal to the height h₂₀ of the openings 20.

The doping of the first layer 110a, 110b is preferably done during the epitaxy of the latter. This enables a better control of the concentration and of the activation of the dopants within the first layer 110a, 110b. It can, however, also be considered, to perform an epitaxy then a doping by implantation.

The masking layer 30 is then removed.

According to an alternative embodiment not illustrated, the first layer 110a, 110b can be formed in the following way, from the assembly illustrated in FIG. 1B. An n-doped or p-doped GaN continuous layer is first formed above the drift layer 130a, 130b of each island 100a, 100b. The thickness of the continuous layer is substantially equal to the height of the openings 20 of the preceding embodiment, h₂₀. An etching step is then carried out in this continuous layer. This etching step is configured to form at least one secondary opening, and preferably a plurality of secondary openings, in the GaN continuous layer of each island 100a, 100b. The etching is moreover configured, such that the secondary openings fully pass through the doped GaN continuous layer, so as to partially reveal the underlying drift layer 130a, 130b. This etching step can be carried out by conventional masking and photolithography techniques.

The remaining portions, i.e. the non-etched portions, of the GaN continuous layer form the doped wells. They therefore form the first layer 110a, 110b. The secondary openings are therefore sized such that the remaining doped wells have the desired dimensions. An epitaxial growth is then performed from the drift layer 130a, 130b in the secondary openings. The drift layer 130a, 130b is thus preferably extended, so as to be flush with the first layer 110a, 110b. The assembly illustrated in FIG. 1D is thus obtained (except for the masking layer 30).

As illustrated in FIG. 1E, an electrically conductive pattern, called anode 500, is then formed on the stack. The anode 500 is in contact with at least two doped wells of one same island 100a, 100b. Advantageously, it is in contact with the doped wells of one same island 100a, 100b. According to an advantageous embodiment illustrated in FIG. 1E, the anode extends continuously above a plurality of islands 100a, 100b. It can thus contact all the doped wells of these islands 100a, 100b, as illustrated.

As illustrated in FIG. 1F, it is then possible to proceed with the removal of the substrate 10 and of the optional buffer layers 15. This removal is typically done by grinding and chemical-mechanical polishing (CMP). Advantageously, a major part of the removal is done by grinding and CMP, then the removal is finalized by selective etching or etching at the time to stop precisely on the lower face 102a, 102b of the islands 100a, 100b.

Advantageously, the removal of the substrate 10 and of the buffer layers 15 occurs after the transfer of the islands 100a, 100b onto a handle substrate (not represented). This transfer occurs on the side of the upper face 101a, 101b of the islands 100a, 100b. The handle substrate is removed after the formation of the drain 400 described further.

The removal of the substrate 10 and of the buffer layers 15 can also occur earlier in the method. The substrate 10 can indeed be removed after the formation of the islands 100a, 100b (and the optional formations of the passivation layer 150 and of the filling layer 160), and before the formation of the first layer 110a, 110b or of the anode 500, between the steps illustrated in FIG. 1B and 1C, 1C and 1D or 1E and 1D. This makes it possible to reduce the mechanical stresses within the stack during the formation of the first layer 110a, 110b and of the anode 500.

After the removal of the substrate 10, the formation of an electrically conductive layer called drain 400 in contact with the lower faces 102a, 102b of the islands 100a, 100b is proceeded with. This drain 400 extends continuously under the islands 100a, 100b. It is thus common to all the diodes 1a, 1b. The formation of the drain 400 is typically done by electrochemical metal deposition.

According to another example, after the removal of the substrate 10 and of the buffer layers 15, the islands 100a, 100b are transferred by their lower faces 102a, 102b onto a highly doped silicon wafer according to an n-type doping. Advantageously, the transfer is done through metal layers favouring bonding and/or electrical conduction between the islands 100a, 100b and the silicon wafer, such as Ti-, Au- and Al-based layers. The drain 400 is then deposited in the rear face of the silicon wafer, opposite the islands 100a, 100b.

According to an alternative embodiment illustrated in FIGS. 1H and 11, rather than removing the substrate 10 and the buffer layers 15, metal interconnections are made. Thus, it is possible, as illustrated in FIG. 1H, to achieve by etching through openings 13 fully passing through the substrate 10 and optionally the buffer layers 15. The through openings 13 thus extend, in particular, from the upper face 11 to the lower face 12 of the support. At least one through opening 13 facing each island 100a, 100b is formed. The through openings 13 are typically formed by a photolithography and etching method. The through openings 13 are then filled with an electrically conductive material, typically a metal, so as to form metal interconnections 14 also passing through the substrate 10 and the buffer layers 15. The drain 400 is thus formed against the lower face 12 of the substrate 10 (FIG. 1I). The drain 400 is formed in contact with at least one metal interconnection 14, preferably, with all the metal interconnections 14. The metal interconnections 14 ensure the electrical connection between the drain 400 and the islands 100a, 100b.

The method thus makes it possible to form at least one diode 1a, 1b, each formed from the following elements:
The drain 400, or the at least one portion of this drain 400,
An island 100a, 100b, comprising GaN layers with distinct dopings, including the drift layer 130a, 130b and the first layer 110a, 110b (in the form of doped wells),
At least one anode 500 deposited in contact with the first layer 110a, 110b of the island 100a, 100b considered, or at least one portion of this anode 500.

The presence of a plurality of doped wells within each diode 1a, 1b makes it possible to increase their power. Advantageously, each diode 1a, 1b comprises at least three doped wells, preferably at least five doped wells.

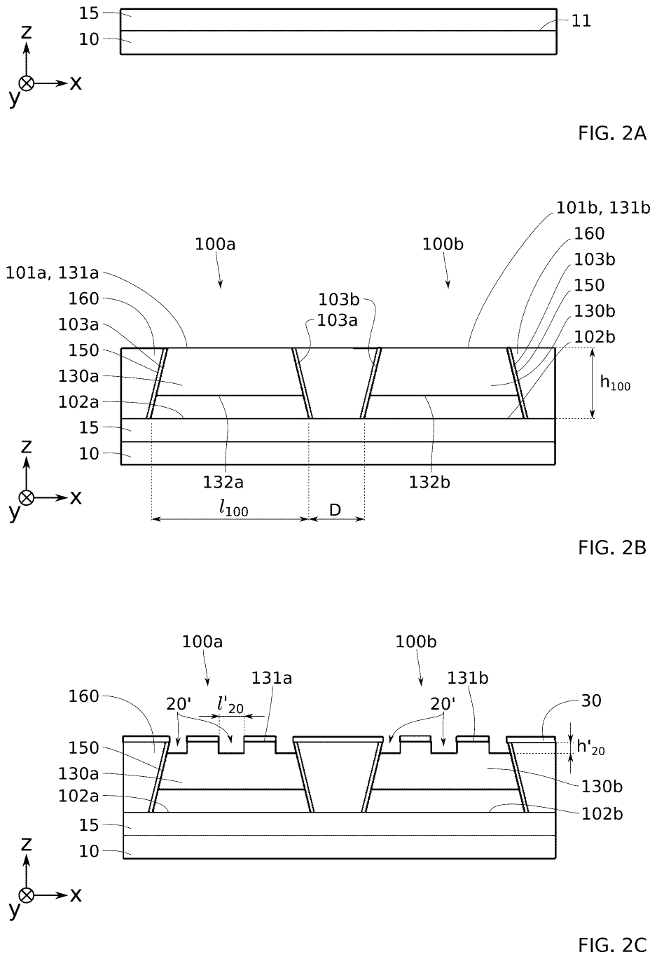

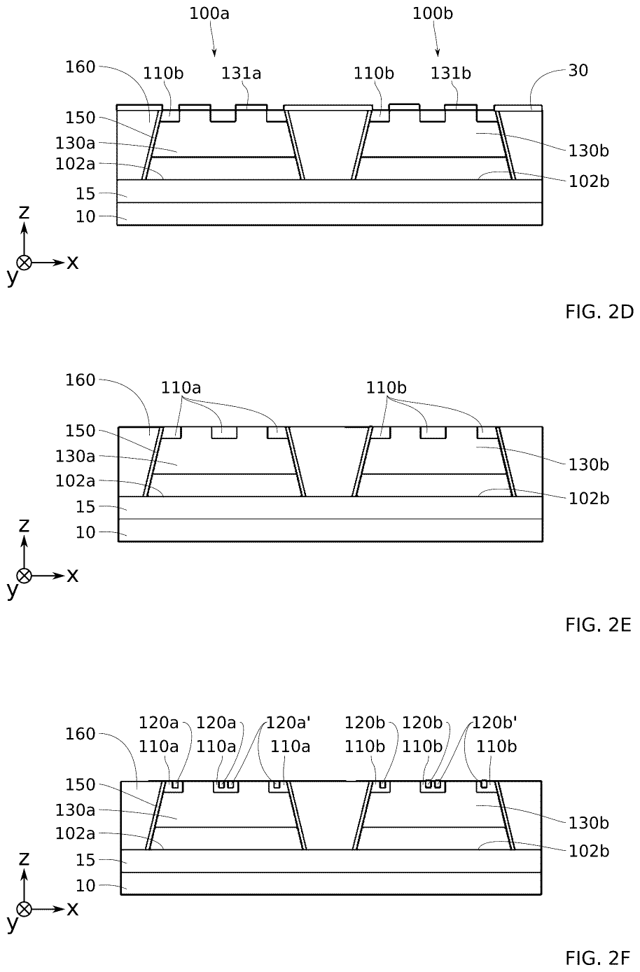

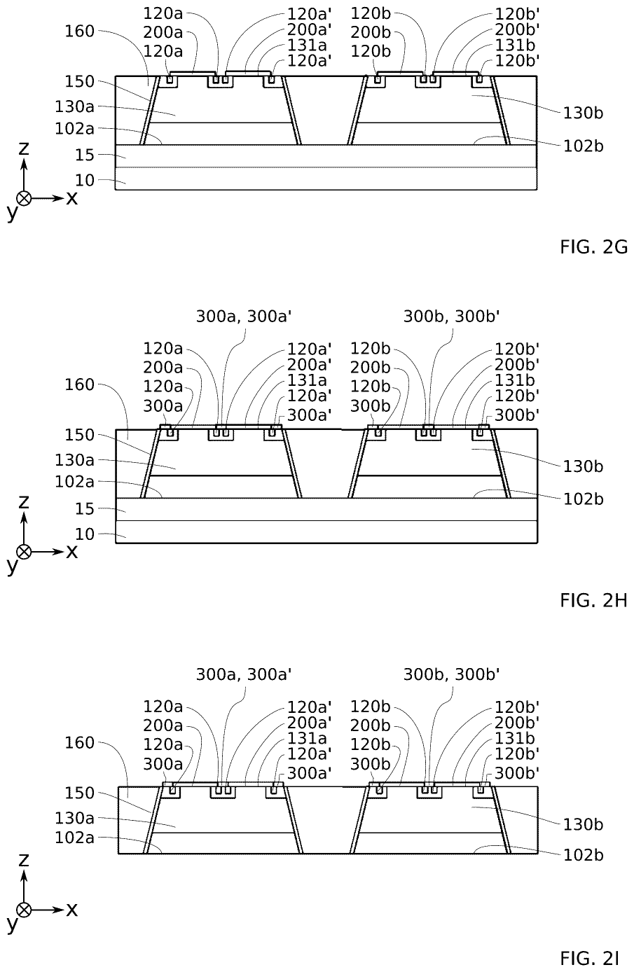

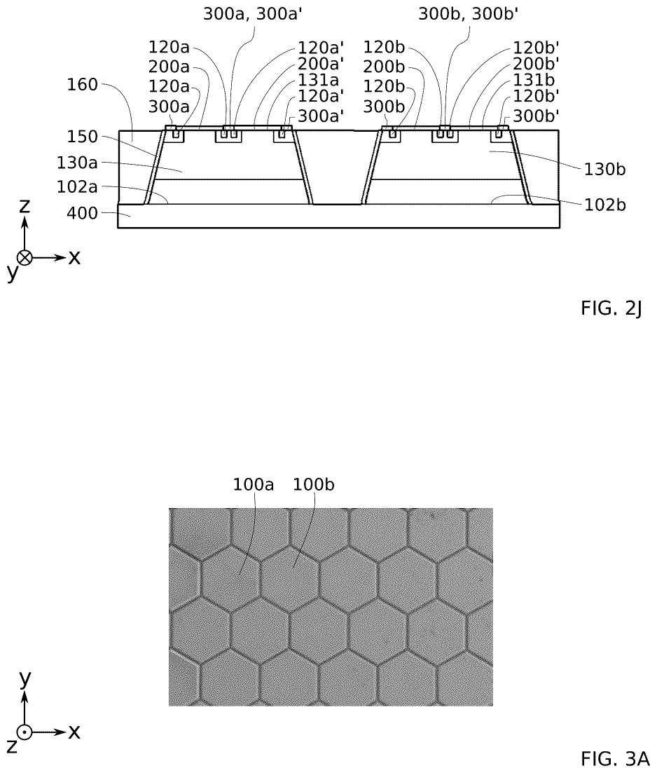

A second embodiment making it possible to manufacture the transistors 2a, 2b will now be described in reference to FIGS. 2A to 2J.

The second embodiment can, for example start like the first embodiment with the provision of a substrate 10 and advantageously, buffer layers 15, as illustrated in FIG. 2A, then the formation of islands 100a, 100b, as illustrated in FIG. 2B. The features described in reference to FIGS. 1A and 1B in the scope of the first embodiment are applied fully, in this case.

An etching step is then carried out from the upper faces 101a, 101b of the islands 100a, 100b. This etching step is configured to form at least two openings 20′, and preferably at least three openings 20′, in each island 100a, 100b. Each opening 20′ partially passes through the drift layer 130a, 130b. As will appear further, the dimensions of the openings 20′ condition those of the active zones of the transistors 2a, 2b. The openings 20′ have, for example, a width I₂₀′ along the first direction X, with I₂₀′ of between 1500 nm and 5000 nm. Along the second direction Y, the openings 20′ preferably fully pass through the islands 100a, 100b. In this case, the openings have, in the longitudinal plane XY, a band shape. Other configuration can, however, be fully considered. The openings 20′ can, in particular, have in the longitudinal plane XY, a square, circular or hexagonal shape. The openings 20′ can be distributed in the longitudinal plane XY along a square network, or a hexagonal network, in particular in the case of openings, themselves having a hexagonal shape. The openings 20′ further have a height h₂₀′ along the stacking direction Z. Whatever the shape of the openings 20′ in the longitudinal plane XY, h₂₀′ is typically greater than or equal to 400 nm.

Fully conventionally, this etching step can be carried out by a dry etching through a masking layer 30, as illustrated in FIG. 2C. For this, conventional photolithography steps can be used.

Similarly to the first embodiment, during a step illustrated in FIG. 2D, a first layer 110a, 110b is formed in the openings 20′ of each island 100a, 100b. The first layer 110a, 110b is doped GaN-based. Its doping, performed during epitaxy or by implantation, can be n-type or p-type. With the first layer 110a being formed in the openings 20, it is discontinuous. It this forms, in the drift layer 130a, 130b, doped regions separated from one another, called doped wells. The width I₁₁₀ of each doped well is substantially equal to the width I₂₀′ of the openings 20′ formed beforehand. The same applies for the thickness e₁₁₀ of the doped wells, substantially equal to the height h₂₀′ of the openings 20′.

The masking layer 30 is then removed (FIG. 2E).

Like in the first embodiment, alternatively, the formation of the first layer 110a, 110b can pass through the following steps:
Deposition of a doped GaN continuous layer on the drift layer 130a, 130b,
Formation of secondary openings in the continuous layer, so as to partially reveal the drift layer 130a, 130b,
Epitaxial growth of the drift layer 130a, 130b through the secondary openings.

Thus, the assembly illustrated in FIG. 2E is obtained.

Then, a localized implantation in the first layer 110a, 110b (FIG. 2F) is proceeded with. This implantation is configured to form at least two doped regions, called source, forming a pair of sources 120a, 120a′, 120b, 120b′. Within a pair of sources 120a, 120a′, 120b, 120b′, a first source is located in a first doped well and a second source is located in a second doped well distinct from the first. One same doped well can accommodate several sources, preferably two sources. FIG. 2F illustrates, for example, at each island 100a, 100b, two pairs of sources distributed in three doped wells. The implantation is advantageously an n-type implantation, with silicon as the implanted species. Following the implantation, preferably an activation annealing is performed. Preferably, the activation annealing is done in the presence of a protective layer surmounting the drift layer 130a, 130b so as to protect the GaN. The protective layer can, for example, be SiN-, SiO₂- or AlN-based.

As illustrated in FIG. 2G, then on each island 100a, 100b, at least one electrically conductive pattern forming part of a gate 200a, 200a′, 200b, 200b′ is formed. Each gate 200a, 200a′, 200b, 200b′ is in contact with the two sources of one same pair. For example, in the figures, the gate having the reference 200a is in contact with the sources referenced 120a. It is understood that each gate 200a, 200a′, 200b, 200b′ can also comprise a semiconductor oxide (for example, SiO₂), called gate oxide or gate dielectric. The gate oxide is in contact with the electrically conductive pattern. The gate oxides are typically formed at this same step.

Then, electrically conductive contacts called source contacts 300a, 300a′, 300b, 300b′ in contact with the sources 120a, 120a′, 120b, 120b′ (FIG. 2H) are formed. As illustrated, a common contact can be formed between sources located in one same doped well. This creates a short-circuit between the two sources, making it possible to avoid the creation of a conductive bipolar transistor in parallel with the manufactured transistors 2a, 2b.

FIGS. 2I and 2J illustrate the removal of the substrate 10 and of the optional buffer layers 15 and the formation of a drain 400′ in contact with the lower face 102a, 102b of the island 100a, 100b. These steps can be carried out in the same way as what has been described above in reference to the first embodiment. They can occur at different moments of the method, for example, between the formation of the islands 100a, 100b and the formation of the first layer 110a, 110b, between the formation of the first layer 110a, 110b and that of the sources 120a, 120a′, 120b, 120b′, between the formation of the sources 120a, 120a′, 120b, 120b′ and that of the gates 200a, 200a′, 200b, 200b′, between the formation of the gates 200a, 200a′, 200b, 200b′ and that of the source contacts 300a, 300a′, 300b, 300b′ or also, after the latter.

Just like in the first embodiment, it is also possible to make metal interconnections in the substrate 10 and in the buffer layers 15 and to form the drain in contact with the lower face 12 of the substrate 10.

The method thus makes it possible to form at least one transistor 2a, 2b, each formed from the following elements:
The drain 400, or the at least one portion of this drain 400,
An island 100a, 100b, comprising GaN layers with distinct dopings including the drift layer 130a, 130b and the first layer 110a, 110b (in the form of doped wells),
At least two sources 120a, 120a′, 120b, 120b′,
At least one gate 200a, 200a′, 200b, 200b′ electrically connecting the two sources,
Source contacts 300a, 300a′, 300b, 300b′ contacting the sources.

Thus, in view of the different embodiments described above, the invention makes it possible to manufacture GaN-based vertical devices, in particular, transistors and diodes, without using a GaN substrate, expensive and often only available in low dimensions.

The invention is not limited to the embodiments described above, and extends to all the embodiments covered by the invention.

1-15. (canceled)

16. A method for manufacturing at least one microelectronic device, the method comprising:
providing a substrate having an upper face;
performing localized epitaxial growth of gallium nitride on the upper face of the substrate to form at least one GaN-based island, each of the at least one GaN-based island having a lower face facing the upper face of the substrate and comprising a GaN-based drift layer having a lower face facing the upper face of the substrate and an upper face opposite the lower face;
for each of the at least one GaN-based island, forming a first doped GaN-based layer having a first conductivity type selected from n-type and p-type, the first doped GaN-based layer forming a plurality of doped wells separated from one another and each extending from the upper face of the drift layer; and
forming an electrically conductive layer that constitutes a drain electrically connected to the lower face of each of the at least one GaN-based island, thereby forming at least one vertical transistor.

17. The method of claim 16, wherein the substrate is a silicon-based substrate.

18. The method of claim 16, wherein each of the at least one GaN-based island has a height greater than or equal to 10 μm, measured in a direction perpendicular to a plane in which the upper face of the substrate extends.

19. The method of claim 16, wherein forming the drain comprises:
after formation of the at least one GaN-based island, removing the substrate; and
forming the drain against the lower face of the at least one GaN-based island.

20. The method of claim 16, wherein forming the drain comprises:
for each of the at least one GaN-based island, forming at least one metal interconnection extending through the substrate and opening onto the GaN-based island; and
forming the drain against a lower face of the substrate opposite the upper face, the drain being in electrical contact with the at least one metal interconnection.

21. The method of claim 16, wherein forming the first doped GaN-based layer comprises:
for each of the at least one GaN-based island, forming at least one opening in the drift layer extending from the upper face of the drift layer; and
forming the first doped GaN-based layer in each of the at least one opening such that the first doped GaN-based layer forms the plurality of doped wells.

22. The method of claim 16, wherein forming the first doped GaN-based layer comprises:
for each of the at least one GaN-based island, forming a continuous doped GaN layer of the first conductivity type on the drift layer;
forming secondary openings in the continuous doped GaN layer, the secondary openings being separated from one another and extending fully through the continuous doped GaN layer to partially expose the drift layer, remaining portions of the continuous doped GaN layer defining the plurality of doped wells; and
epitaxially growing the drift layer within the secondary openings.

23. A method for manufacturing at least one vertical transistor, the method comprising performing the method of claim 16 and further comprising:
for each of the at least one GaN-based island, partially implanting the first doped GaN-based layer to form at least one pair of source regions having a second conductivity type opposite the first conductivity type, the source regions of each pair being located in distinct doped wells;
forming at least one gate in contact with the source regions of each pair, the at least one gate comprising an electrically conductive pattern; and
forming a source contact electrically connected to each source region of each pair.

24. The method of claim 23, wherein the first doped GaN-based layer defines at least three doped wells, and wherein at least two pairs of source regions are formed in the at least three doped wells, with two source regions belonging to different pairs being formed in a same doped well.

25. The method of claim 24, wherein source contacts electrically connected to source regions formed in the same doped well are electrically continuous with one another and define a common source contact for two vertical transistors.

26. The method of claim 23, wherein the substrate is removed prior to formation of the source contact.

27. The method of claim 23, wherein the substrate is removed after formation of the source regions.

28. A method for manufacturing at least one diode, the method comprising performing the method of claim 16 and further comprising forming an electrically conductive anode in contact with at least two of the doped wells.

29. The method of claim 28, wherein the substrate is removed prior to formation of the anode.

30. The method of claim 28, wherein the substrate is removed after formation of the anode.
